(19) United States
(12) Patent Application Publication
(10) Pub. No.: US 2010/0163188 A1
(43) Pub. Date: Jul. 1, 2010

(54) MOUNTING TABLE STRUCTURE AND PROCESSING APPARATUS

(75) Inventors: Sumi Tanaka, Nirasaki (JP); Hiroo Kawasaki, Nirasaki (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/713,226

(22) Filed: Feb. 26, 2010

Related U.S. Application Data
(63) Continuation of application No. PCT/JP2008/065110, filed on Aug. 25, 2008.

(30) Foreign Application Priority Data
Aug. 28, 2007 (JP) 2007-221525

(51) Int. Cl. H01L 21/683; B23Q 3/00; H01L 21/3065; H01L 21/205

(52) U.S. Cl. 156/345.52; 269/289 R; 118/725; 118/500

(57) ABSTRACT

A mounting table structure 54, provided within a processing chamber 22 of a processing apparatus 20 so as to mount thereon a target object to be processed, includes a mounting table 58 made of a dielectric material and having a heating unit 64; and a cylindrical supporting column 56 which is extended upward from a bottom of the processing chamber and is made of a dielectric material and is configured to detachably support the mounting table 58. A cylindrical protection pipe 60 is fixed to a bottom surface of the mounting table 58 and is made of a dielectric material having a diameter smaller than a diameter of the supporting column. A functional rod member 62 is inserted through an inside of the protection pipe 60 and has an upper end in contact with the mounting table 58.

### CROSS-REFERENCES TO RELATED APPLICATIONS

This application is a Continuation-In-Part of International Application No. PCT/JP2008/065110 filed Aug. 25, 2008, which claims the benefits of Japanese Patent Application No. 2007-221525 filed Aug. 28, 2007. The entire disclosure of the prior application is incorporated herein by reference in its entirety.

### FIELD OF THE INVENTION

The present disclosure relates to a processing apparatus for a target object such as a semiconductor wafer, and a mounting table structure.

### BACKGROUND OF THE INVENTION

In general, a semiconductor integrated circuit is fabricated by repetitively performing various single-substrate processes, such as a film forming process, an etching process, a quality modification process and a crystallization process, on a target object such as a semiconductor wafer. When such various processes are performed, necessary processing gases depending on the kinds of the processes are introduced into a processing chamber. For example, a film forming gas or a halogen gas is introduced for the film forming process, an ozone gas or the like is introduced for the quality modification process, and a nonreactive gas such as a N₂ gas or an O₂ gas is introduced for the crystallization process.

For instance, in a single-wafer processing apparatus that performs a heat treatment on every single sheet of semiconductor wafers, a mounting table having, e.g., a resistance heater therein is installed in, an evacuable processing chamber, and a semiconductor wafer is mounted on a top surface of the mounting table. Then, a preset processing gas is flown after the mounting table is heated to a preset temperature (e.g., about 100° C. to about 1000° C.), and various kinds of heat treatments are performed on the wafer under preset processing conditions (Patent Documents 1 to 6). Thus, component members within the processing chamber need to have heat resistance against the heating, and corrosion resistance against the processing gas.

As for a mounting table structure that mounts the semiconductor wafer thereon, a mounting table having heat resistance and corrosion resistance is generally employed. Since metal contamination of this mounting table needs to be prevented, it is formed by burying a resistance heater as a heating element in a ceramic material such as AlN and sintering them as an integrated single body at a high temperature. Likewise, a supporting column is formed in another process by sintering a ceramic material or the like. The mounting table and the supporting column are integrated as one body by being thermally bonded together by, e.g., thermal diffusion welding, thereby constituting the mounting table structure. The mounting table structure formed as a single body in this way is extended upward from a bottom of the processing chamber. In this case, quartz glass having heat resistance and corrosion resistance may be used instead of the ceramic material.

An example of a conventional mounting table structure will be explained. FIG. 11 is a cross sectional view showing the conventional mounting table structure. This mounting table structure is installed within an evacuable processing chamber and includes a circular plate-shaped mounting table 2 made of a ceramic material such as AlN, as illustrated in FIG. 11. A cylindrical supporting column 4 also made of a ceramic material such as AlN is joined to a central bottom surface of the mounting table 2 via a thermal diffusion joint part 6 by, e.g., thermal diffusion welding. Accordingly, the mounting table 2 and supporting column 4 are hermetically joined by the thermal diffusion joint part 6. When a wafer size is about 300 mm, the mounting table 2 has a diameter of about 350 mm and the supporting column 4 has a diameter of about 56 mm. A heating unit 8 made up of, e.g., a heater is installed within the mounting table 2 so as to heat the semiconductor wafer W as the target object mounted on the mounting table 2.

The supporting column 4 is configured to stand upright by being fixed to a chamber bottom 9 by a fixing block 10. Power supply rods 14 are installed within the cylindrical supporting column 4, and upper ends of the power supply rods 14 are coupled to the heating unit 8 via connecting terminals 12. Lower ends of the power supply rods 14 are taken to the outside after penetrating the bottom of the chamber via an insulating member 16. With this configuration, introduction of the processing gas or the like into the supporting column 4 can be prevented, so that corrosion of the power supply rods 14, the connecting terminals 12 or the like due to the corrosive processing gas can be prevented.

Patent Document 1: Japanese Patent Laid-open Publication No. S63-278322

Patent Document 2: Japanese Patent Laid-open Publication No. H07-078766

Patent Document 3: Japanese Patent Laid-open Publication No. H03-220718

Patent Document 4: Japanese Patent Laid-open Publication No. H06-260430

Patent Document 5: Japanese Patent Laid-open Publication No. 2004-356624

Patent Document 6: Japanese Patent Laid-open Publication No. 2006-295138

Meanwhile, when a process on the semiconductor wafer is performed, the mounting table 2 comes into a high temperature state. In this case, the supporting column 4 is made of the ceramic material whose thermal conductivity is not high. However, since the mounting table 2 and the supporting column 4 are joined to each other by the thermal diffusion joint part 6, a great amount of heat escapes from a center of the mounting table 2 toward the supporting column 4 through the supporting column 4. In particular, when the temperature of the mounting table 2 is increased or decreased, the temperature of the central portion of the mounting table 2 is decreased, whereas the temperature of its peripheral portion is increased. Thus, a great temperature difference is generated within the surface of the mounting table 2, resulting in generation of a great thermal stress between the central portion and the peripheral portion thereof. As a consequence, the generated thermal stress causes damage on the mounting table 2.

In particular, depending on the kinds of the processes, the temperature of the mounting table 2 may reach about 700° C. or higher. In such a case, the temperature difference becomes very great, resulting in generation of a great thermal stress. Besides, the damage by the thermal stress may be considerable as the temperature rise and fall of the mounting table is repeated.

Moreover, the mounting table 2 and an upper portion of the supporting column 4 reach high temperature and are thermally expanded. Since, however, a lower end of the supporting column 4 is fixed to the chamber bottom 9 by the fixing block 10, a stress may be concentrated to joint points between the mounting table 2 and the upper portion of the supporting column 4. Thus, the damage may be generated starting from these points.

As a solution to the mentioned problems, it has been attempted to loosely joint the mounting table 2 and the supporting column 4 by a pin or bolt made of a ceramic material, quartz, or the like via a metal sealing member having heat resistance against a high temperature, instead of hermetically joining them as one body by the thermal diffusion joint part 6. In this case, since a small gap exists at the joint portion, a nonreactive gas such as a N₂ gas, an Ar gas or a He gas as a purge gas is introduced into the supporting column 4 so as to prevent introduction of, e.g., the corrosive processing gas into the supporting column 4 through the small gap. In this configuration, since the mounting table and the upper end portion of the supporting column is not strongly coupled, the amount of the heat escaping from the center side of the mounting table to the supporting column side can be reduced, thus preventing exertion of the great thermal stress on the mounting table.

In this case, however, the purge gas fed into the supporting column 4 may be leak into a processing space within the processing chamber through the small gap, resulting in a failure to perform the process under a high vacuum level as well as an increase of running cost due to consumption of a great amount of purge gas.

### BRIEF SUMMARY OF THE INVENTION

In view of the foregoing, the present invention has been conceived to solve the above-mentioned problems efficiently. The present disclosure provides a mounting table structure and a processing apparatus capable of suppressing generation of a great thermal stress on a mounting table, thus preventing damage on the mounting table and reducing a supply amount of a purge gas for preventing corrosion.

In accordance with one aspect of the present invention, there is provided a mounting table structure provided within a processing chamber of a processing apparatus so as to mount thereon a target object to be processed, the processing chamber having a bottom, the mounting table structure including: a mounting table, including a heating unit and made of a dielectric material, configured to mount the target object thereon; a cylindrical supporting column, which is extended upward from the bottom of the processing chamber and made of a dielectric material, configured to detachably support the mounting table; a cylindrical protection pipe having an upper end joined to a bottom surface of the mounting table and made of a dielectric material having a diameter smaller than a diameter of the supporting column; and a functional rod member inserted through an inside of the protection pipe and having an upper end in contact with the mounting table.

With this configuration, by suppressing generation of a great thermal stress on the mounting table, damage of the mounting table can be prevented, and a supply amount of the purge gas for preventing corrosion can be reduced.

In the mounting table structure, a venthole may be provided in a sidewall of the supporting column.

In the mounting table structure, the protection pipe may be joined to a central portion of the mounting table.

In the mounting table structure, the protection pipe may be joined to a peripheral portion of the mounting table.

In the mounting table structure, the protection pipe may be accommodated in the supporting column.

In the mounting table structure, one or a plurality of the functional rod members may be accommodated in the one protection pipe.

In the mounting table structure, a lower end of the protection pipe may be connected to the bottom of the processing chamber via an expansible/contractible bellows.

In the mounting table structure, a nonreactive gas vessel may be installed at a lower end of the protection pipe, and an inside of the protection pipe may be under an atmosphere of a nonreactive gas from the nonreactive gas vessel.

In the mounting table structure, a spring member may be provided to the functional rod member, and the functional rod member may be pressed toward the mounting table by the spring member.

In the mounting table structure, the mounting table and the supporting column may be connected by a connecting pin.

In the mounting table structure, the mounting table and the supporting column may be connected by a hole bolt having a lifter pin hole in a central portion thereof and a fastening nut screwed onto the hole bolt.

In the mounting table structure, the functional rod member may be a heater power supply rod electrically connected with the heating unit.

In the mounting table structure, a chuck electrode for an electrostatic chuck may be installed in the mounting table, and the functional rod member may be a chuck power supply rod electrically connected with the chuck electrode.

In the mounting table structure, a high frequency electrode to which a high frequency power is applied may be installed in the mounting table, and the functional rod member may be a high frequency power supply rod electrically connected with the high frequency electrode.

In the mounting table structure, a combination electrode, which serves as both a chuck electrode for an electrostatic chuck and a high frequency electrode to which a high frequency power is applied, may be installed in the mounting table, and the functional rod member may be a combination power supply rod electrically connected with the combination electrode.

In the mounting table structure, the functional rod member may be a conductive rod of a thermocouple that measures a temperature of the mounting table.

In the mounting table structure, the functional rod member may be an optical fiber of a radiation thermometer that measures a temperature of the mounting table.

In accordance with another aspect of the present invention, there is provided a processing apparatus that performs a process on a target object, the apparatus including: an evacuable processing chamber having a bottom; a mounting table structure configured to mount the target object thereon; and a gas supply unit configured to supply a gas into the processing chamber, wherein the mounting table structure includes: a mounting table, including a heating unit and made of a dielectric material, configured to mount the target object thereon; a cylindrical supporting column, which is extended upward from the bottom of the processing chamber and made of a dielectric material, configured to detachably support the mounting table; a cylindrical protection pipe having an upper end joined to a bottom surface of the mounting table and made of a dielectric material having a diameter smaller than a diameter of the supporting column; and a functional rod member inserted through an inside of the protection pipe and having an upper end in contact with the mounting table.

In accordance with the mounting table structure and the processing apparatus of the present disclosure, the following effects can be achieved. By suppressing the generation of the great thermal stress on the mounting table, the damage of the mounting table itself can be prevented, and the supply amount of the purge gas for corrosion prevention can be reduced.

### BRIEF DESCRIPTION OF THE DRAWINGS

FIG. 1 is a cross sectional configuration view of a processing apparatus including a mounting table structure in accordance with the present disclosure.

FIG. 2 is a plane view showing an example heating unit installed in a mounting table.

FIG. 3 provides a cross sectional view taken along a line A-A of FIG. 1.

FIG. 4 is a partially enlarged cross sectional view illustrating a part corresponding to an inner zone of the heating unit of the mounting table structure of FIG. 1.

FIG. 5 is a diagram illustrating an assembly state of the mounting table structure of FIG. 4.

FIG. 6 is a partially enlarged cross sectional view illustrating a functional bar member configured as a conductive rod of a thermocouple.

FIG. 7 is a partial cross sectional view illustrating a first modification example of a connection structure between the mounting table and a supporting column.

FIG. 8 is a cross sectional view taken along a line B-B of FIG. 7.

FIGS. 9A and 9B are partially enlarged cross sectional views illustrating a second modification example of the connection structure between the mounting table and the supporting column.

FIG. 10 is a cross sectional view illustrating a mounting table to describe a modification example of the thermocouple.

FIG. 11 is a cross sectional view illustrating an example of a conventional mounting table structure.

### DETAILED DESCRIPTION OF THE INVENTION

Hereinafter, an embodiment of a mounting table structure and a processing apparatus in accordance with the present disclosure will be described in detail with reference to the accompanying drawings.

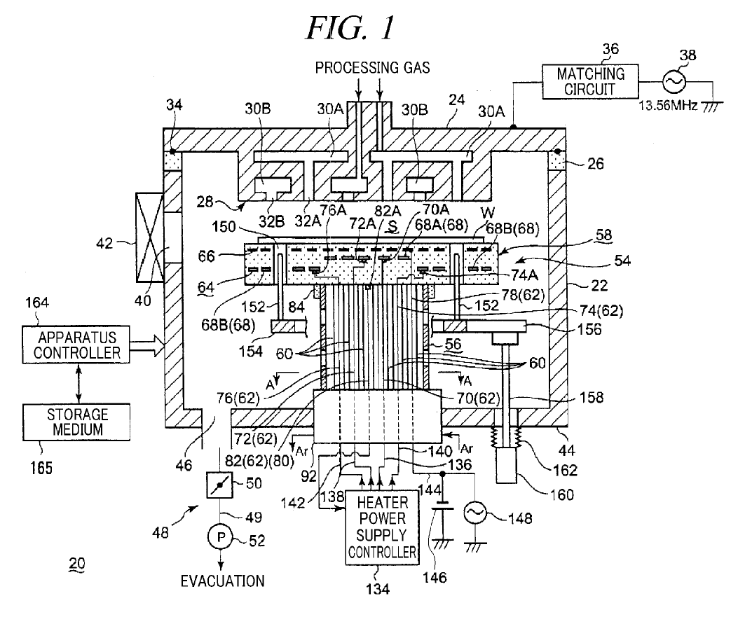

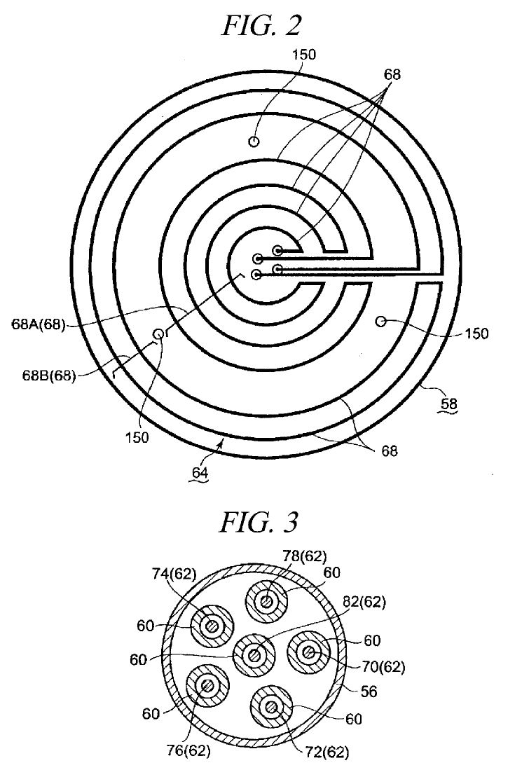

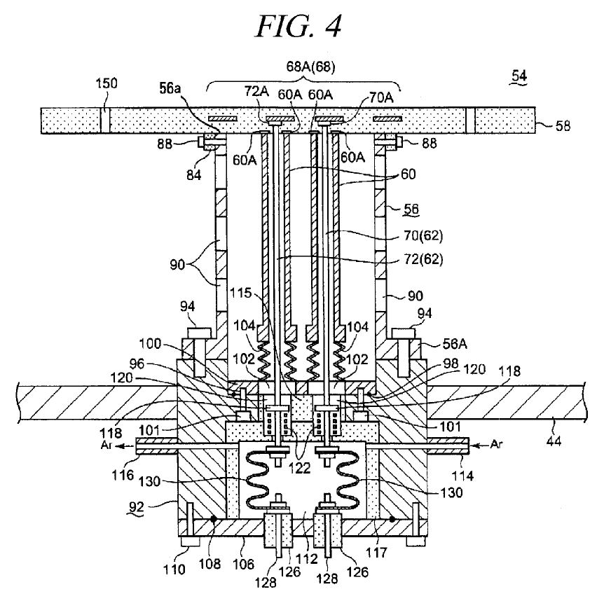

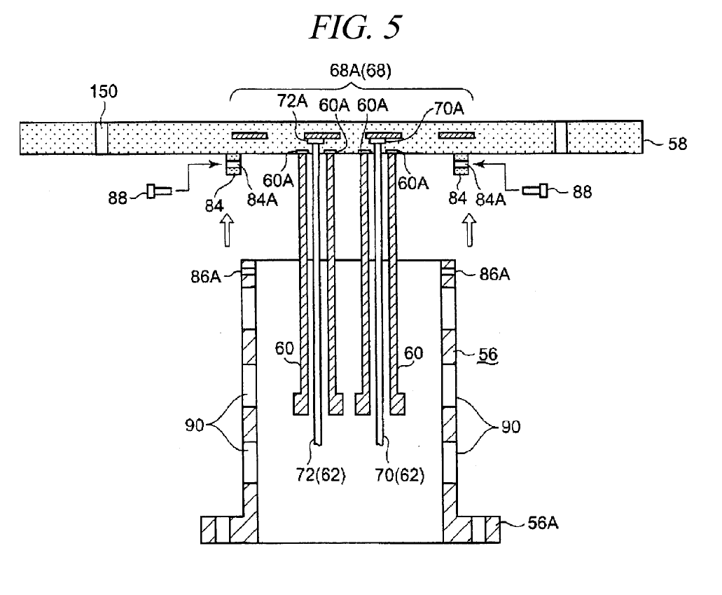

FIG. 1 is a cross sectional configuration view of a processing apparatus including a mounting table structure in accordance with the present disclosure, and FIG. 2 is a plane view illustrating an example heating unit installed in a mounting table. FIG. 3 is a cross sectional view taken along a line A-A of FIG. 1, and FIG. 4 is a partially enlarged cross sectional view illustrating a part corresponding to an inner zone of the heating unit of the mounting table structure of FIG. 1. FIG. 5 is a diagram illustrating an assembly state of the mounting table structure of FIG. 4. Hereinafter, description will be provided for the case of performing a film forming process using plasma.

As shown in the figures, a processing apparatus 20 includes a processing chamber 22 made of, e.g., aluminum and having, e.g., a substantially circular inner cross section. A shower head unit 24 serving as a gas supply unit for introducing a necessary processing gas, e.g., a film forming gas, is installed at a ceiling portion within the processing chamber 22 via an insulating layer 26. The processing gas is discharged toward a processing space S from a multiple number of gas discharge holes 32A and 32B provided in a gas discharge surface 28 on a bottom surface of the shower head unit 24. The shower head unit 24 is also used as an upper electrode during a plasma process.

Two separate hollow gas diffusion spaces 30A and 30B are formed within the shower head unit 24. The processing gas introduced in these spaces is diffused therein in planar direction and then is injected from the respective gas discharge holes 32A and 32B respectively communicating with the gas diffusion spaces 30A and 30B. The gas discharge holes 32A and 32B are arranged in a matrix pattern. The entire shower head unit 24 is made of, e.g., nickel, a nickel alloy such as hastelloy (registered trademark), aluminum or an aluminum alloy. Further, the shower head unit 24 may have only one gas diffusion space.

A sealing member 34 such as an O-ring is provided at a joint portion between the shower head unit 24 and the insulating layer 26 at a top opening portion of the processing chamber 22, whereby the inside of the processing chamber 22 is maintained hermetically sealed. Further, a high frequency power supply 38 of, e.g., about 13.56 MHz for plasma generation is coupled to the shower head unit 24 via a matching circuit 36 so as to generate plasma when necessary. The frequency of the high frequency power supply is not limited to 13.56 MHz.

Furthermore, provided in a sidewall of the processing chamber 22 is a loading/unloading port 40 through which a semiconductor wafer W as a target object is loaded into or unloaded from the processing chamber 22. A gate valve 42 capable of being opened and closed hermetically is installed at the loading/unloading port 40. An exhaust port 46 is provided at a peripheral portion of a bottom 44 of the processing chamber 22, and an exhaust system 48 for evacuating the inside of the processing chamber 22 is connected to the exhaust port 46. The exhaust system 48 has an exhaust path 49 connected to the exhaust port 46. A pressure control valve 50 and a vacuum pump 52 are installed in the exhaust path 49 in sequence so as to maintain the processing chamber 22 at a desired pressure.

A mounting table structure 54, which is an inventive feature of the present disclosure, is installed at the bottom 44 of the processing chamber 22. To elaborate, the mounting table structure 54 includes a cylindrical supporting column 56 extended upward (standing upright) from the bottom of the processing chamber 22; a mounting table 58 detachably connected to and supported on an upper end 56a (FIG. 4) of the supporting column 56; a plurality of protection pipes 60 having upper ends 60A connected to the mounting table 58; and functional rod members 62 inserted through the inside of the protection pipes 60.

In FIG. 1, the supporting column 56 is shown to be enlarged for the purpose of illustration. Specifically, both the mounting table 58 and the supporting column 56 are made of, e.g., a ceramic material such as aluminum nitride (AlN) which is a dielectric material having thermal resistance. A heating unit 64 and a combination electrode 66 are embedded in the mounting table 58, and the semiconductor wafer W can be mounted on a top surface thereof. Further, the supporting column 56 may be made of a different material from that of the mounting table 58. For example, by forming the supporting column 56 with quartz or the like having low thermal conductivity, heat transfer from the mounting table 58 to the supporting column 56 can be further suppressed.

As illustrated in FIG. 2, the heating unit 64 includes heating elements 68 made of a refractory metal or a carbon wire heater, and the heating elements 68 are installed in the substantially entire surface of the mounting table 58 in a preset pattern. Here, the heating elements 68 are divided into an inner-zone heating element 68A on the center side of the mounting table 58 and an outer-zone heating element 68B outside the inner-zone heating element 68A in a manner that they are electrically separated in the two different zones. Connecting terminals of the heating elements 68A and 68B in the respective zones are gathered at the center side of the mounting table 58. Alternatively, the number of the zones may be one or more than three.

Further, the combination electrode 66 is installed directly under the top surface of the mounting table 58. The combination electrode 66 is made of a conductive line formed in, e.g., a mesh shape, and a connecting terminal of the combination electrode 66 is located at a central portion of the mounting table 58. Here, the combination electrode 66 functions both as a chuck electrode for an electrostatic chuck and as a high frequency electrode serving as a lower electrode to which a high frequency power is applied.

Further, each functional rod member 62 serves as a power supply rod that supplies power to the heating elements or the combination electrode 66, or serves as a conductive rod of a thermocouple that measures a temperature. The functional rod members 62 are respectively inserted through the inside of the narrow protection pipes 60.

As illustrated in FIGS. 1 and 3, six protection pipes 60 are installed within the supporting column 56 so as to be collected at the central portion of the mounting table 58. Each protection pipe 60 is made of a dielectric material. Specifically, each protection pipe 60 is made of the same material as that of the mounting table 58, e.g., aluminum nitride, and is airtightly fixed to the bottom surface of the mounting table 58 as one body by, e.g., thermal diffusion welding. Accordingly, a thermal diffusion joint part (see FIG. 4) is formed at the upper end 60A of each protection pipe 60. The functional rod members 62 are inserted through the inside of the respective protection pipes 60. FIG. 4 illustrates connection states of power supply rods to the inner-zone heating element 68A as described above.

For the inner-zone heating element 68A, heater power supply rods 70 and 72 as two separate functional rod members 62 for power-in and power-out are respectively inserted through the inside of individual protection pipes 60, and are electrically coupled to the inner-zone heating element 68A via connecting terminals 70A and 72A at upper ends of the heater power supply rods 70 and 72, respectively.

Further, for the outer-zone heating element 68B, heater power supply rods 74 and 76 as two separate functional rod members 62 for power-in and power-out are respectively inserted through the inside of individual protection pipes 60, and are electrically coupled to the outer-zone heating element 68B via connecting terminals 74A and 76A at upper ends of the heater power supply rods 74 and 76, respectively (see FIG. 1). Each of the heater power supply rods 70 to 76 is made of, e.g., a nickel alloy.

Moreover, for the combination electrode 66, a combination power supply rod 78 as a functional rod member 62 is inserted through a protection pipe 60, and is electrically coupled to the combination electrode 66 via a connecting terminal at an upper end of the combination power supply rod 78. The combination power supply rod 78 is made of, e.g., a nickel alloy.

In addition, a conductive rod 82 of a thermocouple 80 as a functional rod member 62 is inserted through the remaining one protection pipe 60 to measure the temperature of the mounting table 58. Further, a thermometric contact point 82A of the thermocouple 80 is positioned in a central bottom surface of the mounting table 58.

A ring-shaped flange 84 (see FIGS. 4 and 5) is formed on the bottom surface of the mounting table 58 so as to be connected with the supporting column 56, and the flange 84 is provided with a plurality of pin holes 84A. Further, pin holes 86A (see FIG. 5) are also provided at the upper end 56a of the supporting column 56, respectively corresponding to the pin holes 84A. By inserting fixing pins 88 through the pin holes 84A and 86A, the mounting table 58 and the supporting column 56 are connected relatively loosely lest the mounting table 58 be separated from the supporting column 56, whereby a thermal stress generated at this part can be alleviated. To elaborate, an inner diameter of the flange 84 is set to be slightly larger than an outer diameter of the upper end of the supporting column 56. In this way, by providing a small gap (not shown) between the two components, their difference in thermal expansion can be allowed.

Further, ventholes 90 having a relatively large diameter are formed in a sidewall of the supporting column 56, whereby a gas in the processing chamber 22 is prevented from staying in this supporting column 56. A ring-shaped fixing flange 56A is installed at a lower end of the supporting column 56. Further, the bottom 44 of the processing chamber 22 is made of, e.g., stainless steel, and a cylindrical mounting base 92 made of a metal such as stainless steel is fixed at a central portion thereof. The flange 56A at the lower end of the supporting column 56 is installed on the mounting base 92 and fixed thereto by bolts 94, whereby the supporting column 56 is fixed in the upright position (see FIG. 4). The bolts 94 are made of, e.g., stainless steel.

A ring-shaped mounting portion 96 having an opening at the center thereof is formed at a middle portion of the mounting base 92. A sealing plate 100 made of a metal plate such as stainless steel is fixed to a top surface of the mounting portion 96 by bolts 101 via a sealing member 98 such as an O-ring.

The sealing plate 100 is provided with insertion through holes 102 (only two are shown in FIG. 4) respectively corresponding to the protection pipes 60, i.e., the functional rod members 62. The respective functional rod members 62 are inserted through the insertion through holes 102. That is, the heater power supply rods 70, 72, 74 and 76, the combination power supply rod 78 and the conductive rod 82 of the thermocouple 80 as the functional rod members 62 are inserted through the insertion through holes 102, respectively.

Expansible/contractible/flexible bellows 104 made of a metal such as stainless steel are airtightly installed between the lower ends of the respective protection pipes 60 and the sealing plate 100 so as to allow thermal expansion/contraction or horizontal movement of the protection pipes 60.

Moreover, a bottom plate 106 made of a metal plate such as stainless steel is airtightly fixed to the lower end of the cylindrical mounting base 92 via a sealing member 108 such as an O-ring by, e.g., bolts 110, and a nonreactive gas vessel 112 is formed inside thereof. In the nonreactive gas vessel 112, a nonreactive gas inlet 114 and a nonreactive gas outlet 116 are installed through a sidewall of the mounting base 92 so as to supply a nonreactive gas into the nonreactive gas vessel 112. As the nonreactive gas, a gas including a rare gas such as an Ar gas or a He gas can be used besides a N₂ gas.

Insulating members 117 and 115 made of, e.g., alumina are installed at inner surfaces of the nonreactive gas vessel 112 except its bottom surface and at the opening of the mounting portion 96, respectively.

The lower ends of the respective functional rod members 62 are extended into the nonreactive gas vessel 112 through the insulating members 117 and 115. Further, a spring receiving unit 118 having a larger-diameter is installed in the middle of a lower end portion of each functional rod member 62. Further, a spring receiving hole 120 allowing each spring receiving unit 118 to be vertically movable therein is formed by cutting off a portion corresponding to the entire depth of the upper insulating member 115 and a part of the lower insulating member 117.

A spring member 122 made of, e.g., a coil spring is installed between the bottom of each spring receiving hole 120 and each spring receiving unit 118 so as to press the respective functional rod members 62 toward the mounting table 58 above.

In this case, when each functional rod member 62 penetrates the bottom of corresponding one of the spring receiving holes 120 downward, a small gap is formed at this penetration portion. The nonreactive gas within the nonreactive gas vessel 112 flows up through this gap and is supplied into the protection pipe 60, whereby a nonreactive gas atmosphere is generated in the protection pipe 60.

As for such a configuration, although only the heater power supply rods 70 and 72 as the functional rod members 62 of the inner-zone heating element 68A are shown in FIG. 4 for illustration, the other functional rod members 62, that is, the heater power supply rods 74 and 76 for the outer-zone heating element 68B, the combination power supply rod 78 and the conductive rod 82 of the thermocouple 80 also have the same configuration.

Outgoing terminals 128 respectively corresponding to the functional rod members 62 and hermetically insulated by insulating members 126 are configured to penetrate a bottom plate 106 of the nonreactive gas vessel 112. In FIG. 4, only two outgoing terminals 128 are shown. The lower ends of the functional rod members 62 and the outgoing terminals 128 are electrically connected with each other via conductive members 130 made of, e.g., flexible and compressible/extensible metal plates, whereby the functional rod members 62 can be allowed to be electrically connected with the outside while their thermal expansion and contraction are allowed.

Moreover, the conductive member 130 may be fabricated by a metal wiring having a sufficient length. The above-described structure with the conductive member 130 is also applied to the other heater power supply rods 74 and 76 and the combination power supply rod 78. When, however, the functional rod member 62 is the conductive rod 82 of the thermocouple, it can be directly taken out to the outside hermetically via a through hole 131 and a bellows 132 thereat without using a conductive member 130.

Here, example sizes of the respective components will be explained. A diameter of the mounting table 58 is about 340 mm, 230 mm and 460 mm when it corresponds to a wafer having a diameter of about 300 mm (12 inches), 200 mm (8 inches) and 400 mm (16 inches), respectively. Further, a diameter of the supporting column 56 is about 50 to about 80 mm regardless of the size of the mounting table 58. Further, a diameter of each protection pipe 60 is about 8 to about 16 mm, and a diameter of each functional rod member 62 is about 4 to about 6 mm.

Referring back to FIG. 1, the conductive rod 82 of the thermocouple 80 is connected to a heater power supply controller 134 having, e.g., a computer. Further, wirings 136, 138, 140 and 142 connected to the heater power supply rods 70, 72, 74 and 76 of the heating unit 64 are also connected to the heater power supply controller 134. Based on a temperature measured by the thermocouple 80, the inner-zone heating element 68A and the outer-zone heating element 68B are individually controlled so as to maintain a desired temperature.

In addition, a DC power supply 146 for electrostatic chuck and a high frequency power supply 148 for applying a high frequency bias power are respectively connected with a wiring 144 coupled to the combination power supply rod 78. With this configuration, the wafer W on the mounting table 58 can be electrostatically attracted and held thereon, and a high frequency power as a bias can be applied to the mounting table 58, which serves as a lower electrode during a process. A frequency of this high frequency power may be about 13.56 MHz, but not limited thereto. For example, about 400 MHz can also be used.

Further, the mounting table 58 is provided with a plurality of, e.g., three pin insertion through holes 150 (only two are shown in FIG. 1) which penetrate it in a vertical direction. Elevating pins 152 are inserted into the respective pin insertion through holes 150 in a vertically movable state, and a elevating ring 154 made of a ceramic material such as alumina and having an circular arc shape is installed at lower ends of the elevating pins 152. The lower ends of the elevating pins 152 are placed on the elevating ring 154. An arm 156 extended from the elevating ring 154 is connected with an elevating rod 158 which is installed so as to penetrate the chamber bottom 44, and the elevating rod 158 can be moved up and down by an actuator 160.

With this configuration, the elevating pins 152 can be protruded above the upper ends of the pin insertion through holes 150 when the wafer W is transferred. Further, an expansible/contractible bellows 162 is installed at a portion where the elevating rod 158 penetrates the chamber bottom, the elevating rod 158 can be moved up and down while maintaining airtightness within the processing chamber 22.

The entire operation of the processing apparatus 20 such as control of a processing pressure, control of the temperature of the mounting table 58, supply or stop of the processing gas, and so forth, is conducted by an apparatus controller 164 made up of, e.g., a computer. The apparatus controller 164 includes a storage medium 165 storing therein computer programs for executing the mentioned operations. The storage medium 165 may be implemented by a floppy disk, a CD (Compact Disk), a hard disk, a flash memory, or the like.

Now, an operation of the processing apparatus using plasma and having the above-described configuration will be explained. First, an unprocessed semiconductor wafer W is loaded into the processing chamber 22 by being held on a non-illustrated transfer arm through the open gate valve 42 and the loading/unloading port 40. Then, after the wafer W is transferred onto the elevating pins 152 in raised position, the elevating pins 152 are lowered, whereby the wafer W is mounted on the top surface of the mounting table 58 sustained on the supporting column 56 of the mounting table structure 54. At this time, by applying a DC voltage to the combination electrode 66 of the mounting table 58 from the DC power supply 146, the electrostatic chuck is operated, so that the wafer W is attracted to and held on the mounting table 58. Alternatively, a clamp mechanism configured to press a periphery portion of the wafer W may be used instead of the electrostatic chuck.

Subsequently, various processing gases are supplied into the shower head unit 24 while their flow rates are being controlled, and these gases are introduced into the processing space S by being injected from the gas discharge holes 32A and 32B. Then, by keeping operating the vacuum pump 52 of the exhaust system 48, the inside atmosphere of the processing chamber 22 is evacuated, and by controlling opening degree of the pressure control valve 50, the atmosphere of the processing space S is maintained at a preset processing pressure. At this time, the temperature of the wafer W is maintained at a preset processing temperature. That is, by applying voltages to the inner-zone heating element 68A and the outer-zone heating element 68B constituting the heating unit 64 by the heater power supply controller 134, the heating elements generate heat.

As a result, the wafer W is heated by the heat from the heating elements 68A and 68B, and its temperature is increased. At this time, the thermocouple 80 installed at the central bottom surface of the mounting table 58 measures the temperature of the wafer (mounting table), and based on this measurement value, the heater power supply controller 134 controls the temperature of each zone. Accordingly, the temperature of the wafer W can always be controlled with high uniformity in a wafer surface. In this case, depending on the kind of processes, the temperature of the mounting table 58 may reach, e.g., about 700° C.

Moreover, when a plasma process is performed, a high frequency power is applied between the shower head unit 24 serving as an upper electrode and the mounting table 58 serving as a lower electrode by the high frequency power supply 38. As a result, plasma is generated in the processing space S, and the preset plasma process is performed. Further, by applying a high frequency power to the combination electrode 66 of the mounting table 58 by the high frequency bias power supply 148, plasma ions can be attracted.

Hereinafter, the function of the mounting table structure 54 will be discussed in detail. First, power is supplied to the inner-zone heating element 68A of the heating unit via the heater power supply rods 70 and 72, which are functional rod members 62, and to the outer-zone heating element 68B via the heater power supply rods 74 and 76. Further, the heater power supply controller 134 is informed of a temperature of a central portion of the mounting table 58 via the conductive rod 82 of the thermocouple 80 installed in a manner that its thermometric contact point 82A contacts the central bottom surface portion of the mounting table 58. In this case, the thermometric contact point 82A measures the temperature of the inner-zone, and the power supplied to the outer-zone heating element 68B is determined based on a predetermined power ratio between the powers supplied to the inner-zone heating element 68A and the outer-zone heating element 68B.

Further, a DC voltage for electrostatic chuck and a high frequency bias power are applied to the combination electrode 66 via the combination power supply rod 78. The respective heater power supply rods 70, 72, 74 and 76, the conductive rod 82 and the combination power supply rod 78, which are functional rod members 62, are individually inserted through the insides of the narrow protection pipes 60 whose upper ends are hermetically fixed to the bottom surface of the mounting table 58 by thermal diffusion welding.

In addition, an Ar gas as a nonreactive gas is supplied into the nonreactive gas vessel 112 installed below the supporting column 56, and the Ar gas is filled in the respective protection pipes 60 through the gaps between the respective functional rod members 62 and the insulating members 115 and 117 enclosing the nonreactive gas vessel 112 and through the spring receiving holes 120.

Under such circumstances, temperature rise and fall of the mounting table 58, on which processing on the wafer W is repetitively performed, are repeated. Along with the temperature rise and fall of the mounting table 58, a thermal expansion difference as much as a distance of about 0.2 to about 0.3 mm in a radial direction is generated between the central portion of the mounting table 58 and the supporting column 56 when the temperature of the mounting table 58 reaches, for example, about 700° C., as mentioned above. In such a case, in a conventional mounting table structure in which a mounting table made of a very hard ceramic material and a supporting column having a larger diameter are strongly coupled as one body by thermal diffusion welding, a joint portion between the mounting table and the supporting column has been damaged due to repeated thermal stress caused by the thermal expansion difference, although the difference is as small as about 0.2 to about 0.3 mm.

In contrast, in the present embodiment, since the mounting table 58 is loosely connected with the supporting column 56, the mentioned thermal expansion difference can be allowed. To elaborate, since the inner diameter of the flange 84 on the bottom surface of the mounting table 58 is set to be slightly larger than the outer diameter of the upper end 56a of the supporting column 56 by, e.g., about 0.6 mm in order to provide a gap between them, the thermal expansion difference can be allowed. As a result, a thermal stress is not applied, and thus, damage on the upper end 56a of the supporting column 56 or the bottom surface of the mounting table 58, i.e., the joint portion therebetween can be avoided.

In this case, although the respective protection pipes 60 made of the ceramic material are strongly fixed to the bottom surface of the mounting table 58 by thermal diffusion welding, the amount of heat transfer from the mounting table 58 to the respective protection pipes 60 can be reduced because the diameter of the protection pipes 60 is set to be about 10 mm, much smaller than the diameter of the supporting column 56, as described above. Further, since the joint portion between the mounting table 58 and the supporting column 56 is loose, their contact area is reduced, which in turn results in an increase of thermal resistance at that portion. Thus, the amount of heat transfer toward the supporting column 56 can be reduced.

Moreover, although the protection pipes 60 are thermally expanded and contracted as the wafer processing is repeated, the thermal expansion and contraction of the protection pipes 60 are allowed as the bellows 104 installed below the respective protection pipes 60 are expanded and contracted. Thus, damage of the protection pipes 60 and the mounting table 58 can be prevented.

In addition, since the functional rod members 62 are respectively enclosed by the protection pipes 60 and the nonreactive gas as a purge gas is supplied in the protection pipes 60 from the nonreactive gas vessel 112 installed below the protection pipes 60, the functional rod members 62 are protected from a corrosive processing gas, and oxidation of the functional rod members 62 or the connecting terminals 70A to 82A can be prevented by the nonreactive gas. Furthermore, since leakage of the nonreactive gas into the processing chamber 22 does not occur, unlike the conventional mounting table structure, a high-vacuum process can be carried out, and a consumption amount of the nonreactive gas can be reduced, thus enabling cost-cut.

Further, since the spring members 122 are installed at the lower ends of the functional rod members 62 so as to press the functional rod members 62 to the above mounting table 58, an electric contact fail can be prevented. Further, with this configuration, since the thermometric contact point 82A of the thermocouple 80 is prevented from being separated from the bottom surface of the mounting table 58, temperature can be measured accurately. Besides, since the large ventholes 90 are provided in the sidewall of the supporting column 56, stay of various gases within the supporting column can be prevented.

### First Modification Example of the Connection Structure Between the Mounting Table and the Supporting Column

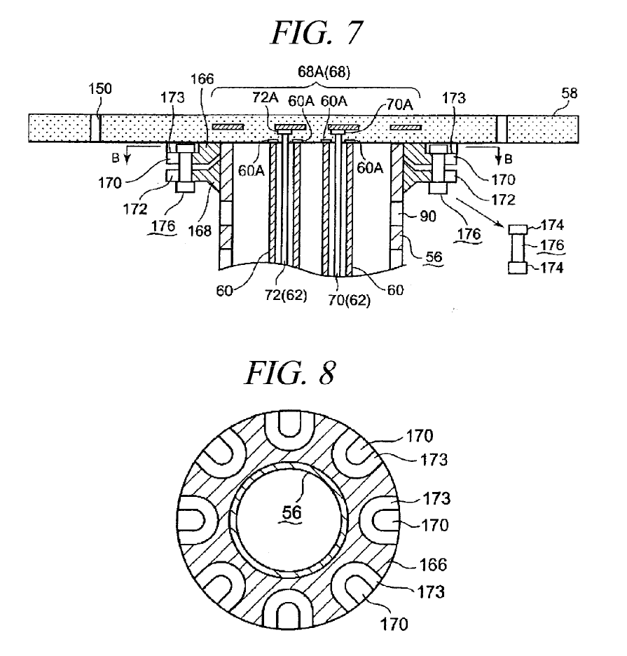

In the above-described embodiment, the mounting table 58 and the supporting column 56 are connected by installing the ring-shaped flange 84 on the bottom surface of the mounting table 58 and fixing the upper end 56a of the supporting column 56 to the flange 84 by the fixing pins 88. However, the connection structure is not limited thereto but can be configured as illustrated in FIGS. 7 and 8. FIG. 7 is a partial cross sectional view showing a first modification example of the connection structure between the mounting table and the supporting column, and FIG. 8 is a cross sectional view taken along a line B-B of FIG. 7.

In this example, as shown in FIGS. 7 and 8, a thick ring-shaped flange 166 is formed at a central bottom surface portion of the mounting table 58, and a ring-shaped flange 168 corresponding to the flange 166 is also formed at an outer peripheral side of an upper end of the supporting column 56. The flanges 166 and 168 are all made of a ceramic material, e.g., aluminum nitride and are formed as one body with their base members.

The flange 166 on the side of the mounting table 58 is provided with eight bisected grooves 170 opened outward and arranged at a certain distance along a circumferential direction thereof. However, the number of the holes is not particularly limited. Further, a stepped portion 173 lowered by one step from the flange 166 is formed at the periphery of each bisected groove 170.

Further, the flange 168 on the side of the supporting column 56 is also provided with bisected grooves 172 corresponding to the bisected grooves 170 and having the same shape as them. The flanges 166 and 168 are coupled by connecting pins 176 installed between the facing bisected grooves 170 and the 172. As illustrated in FIG. 7, each connecting pin 176 has head portions 174 at both ends thereof, and each head portion 174 has a diameter slightly larger than a width of the bisected grooves 170 and 172. In FIG. 8, illustration of such connecting pins is omitted. The connecting pins 176 are made of, e.g., a ceramic material such as aluminum nitride and can be formed by being cut from a ceramic block as a single body.

As for the insertion of the connecting pins 176, the mounting table 58 is manually pressed downward against an elastic force of the bellows 104 (see FIG. 4) at the lower ends of the functional rod members 62, and the connecting pins 176 are inserted into both bisected grooves 170 and 172. Then, when hands are taken off, the mounting table 58 is pressed upward by the bellows 104, whereby both flanges 166 and 168 can be connected by the connecting pins 176. In this case, as the connecting pins 176 are moved along the bisected grooves 170 and 172 in a radial direction, the thermal expansion difference between the mounting table 58 and the supporting column 56 can be tolerated, as in the above-described embodiment.

### Second Modification Example of the Connection Structure Between the Mounting Table and the Supporting Column

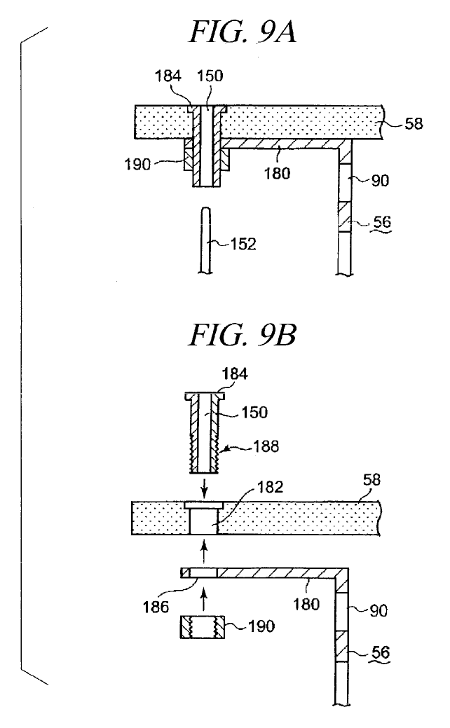

Now, a second modification example of the connection structure between the mounting table and the supporting column will be explained. FIGS. 9A and 9B are partially enlarged cross sectional views illustrating the second modification example of the connection structure between the mounting table 58 and the supporting column 56. FIG. 9A provides a partially enlarged cross sectional view and FIG. 9B illustrates an exploded assembly state thereof.

As illustrated in FIGS. 9A and 9B, the width of a ring-shaped flange 180 installed at an upper end of the supporting column 56 is set to be large in a radial direction, so that the flange 180 is extended up to a position slightly beyond the pin insertion through holes 150 of the mounting table 58 (see FIG. 1). Then, a bolt hole 182 having a large diameter is formed in the mounting table 58, and a bolt hole 186 having the same size as the bolt hole 182 is also formed in the flange 180. Then, after the mounting table 58 and the flange 180 are arranged for each other, a hole bolt 184, which has a head and a pin insertion through hole 150 at its central portion, is inserted through the bolt holes 182 and 186. Here, the pin insertion through hole 150 penetrates through the hole bolt 184 in an axial direction of the hole bolt 184.

A screw thread 188 is formed at a lower part of the hole bolt 184. As stated above, after the hole bolt 184 is inserted through both the bolt holes 182 and 186, a fastening nut 190 is screwed onto the screw thread 188 of the hole bolt 184, whereby the two components are firmly fastened to each other. In such a case, an inner diameter of the bolt hole 182 of the mounting table 58 is set to be slightly larger than an outer diameter of the hole bolt 184 to thereby provide a small gap having a width capable of absorbing a thermal expansion difference therebetween.

In this example, the same effect as obtained in the above embodiment can be achieved. Further, in this case, the hole bolt 184 and the fastening nut 190 are made of a ceramic material or a metal such as an aluminum alloy.

### Modification Example of the Thermocouple

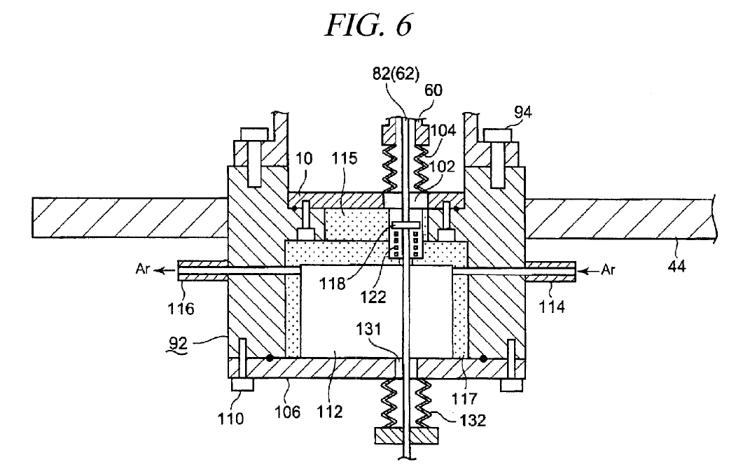

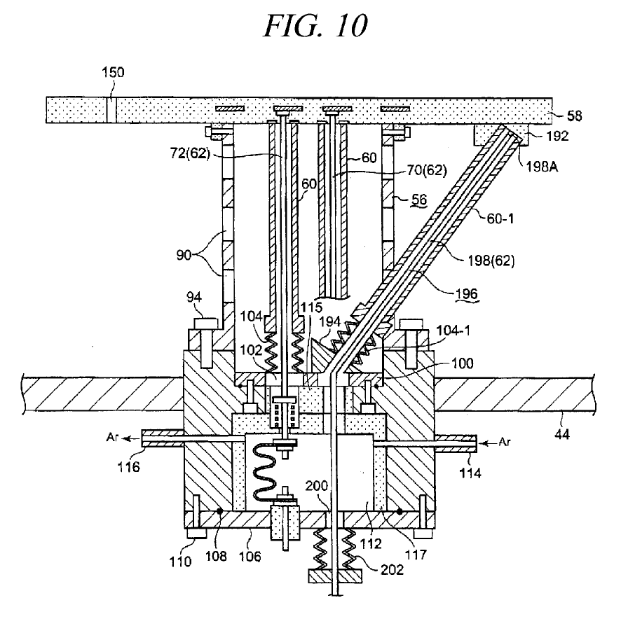

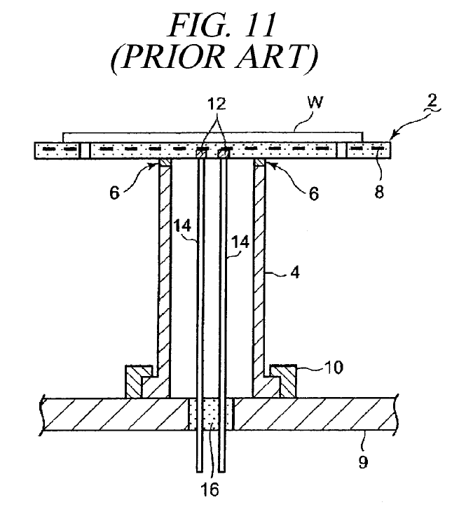

In the above-described embodiment, although one thermocouple is provided so as to measure an inner-zone temperature of the mounting table 58, the present invention is not limited thereto, and one thermocouple can be additionally installed so as to measure an outer-zone temperature. FIG. 10 provides a cross sectional view illustrating a mounting table structure to describe such a modification example of the thermocouple. In the figure, the same constituent parts as illustrated in FIGS. 1 to 6 are assigned same reference numerals.

As shown in FIG. 10, one protection pipe 60-1 is protruded from a lower position of the supporting column 56 and is extended horizontally and upwardly in an inclined direction, inclined upward. An upper end of this protection pipe 60-1 is fixed to a bottom surface of the mounting table 58 via a joint block 192 made of a ceramic material such as aluminum nitride. In this case, the mounting table 58 and the joint block 192, and the joint block 192 and the upper end of the protection pipe 60-1 are joined as one body by thermal diffusion welding. Further, the joint block 192 is installed at a portion corresponding to an outer zone of the mounting table 58.

An attachment auxiliary member 194 made of a metal such as stainless steel, having a triangular cross section and provided with an insertion through hole is installed at the sealing plate 100 at the bottom side of the supporting column 56, and a bellows 104-1 is installed between the attachment auxiliary member 194 and a lower end of the protection pipe 60-1. Further, a conductive rod 198 (functional rod member 62) serving as an outer-zone thermocouple 196 is inserted through the inside of the protection pipe 60-1, and a thermometric contact point 198A of a leading end thereof is in contact with the joint block 192 so as to measure the outer-zone temperature.

Further, a lower end of the conductive rod 198 is inserted downward through a through hole 200 in the bottom plate 106 forming the nonreactive gas vessel 112, and an expansible/contractible bellows 202 is installed at the through hole 200. Further, it may be possible to provide such a spring member 122 as described in FIG. 4 in the middle of the conductive rod 198 to press the conductive rod 198 upward.

Further, the bellows 104-1 or the bellows 202 may be configured to have the function same as the spring member 122. In this example, the same effect as stated above can be achieved, and since the inner-zone temperature and the outer-zone temperature can be measured individually, the temperature of the mounting table 58 (wafer temperature) can be controlled more accurately.

In the above-described embodiment, although the combination electrode 66 is installed in the mounting table 58 and the DC voltage for electrostatic chuck and the high frequency bias power are applied to the combination electrode 66 through the combination power supply rod 78, it may be also possible to install separated electrodes and power supply rods, or to install an electrode and a power supply rod. For example, when the separated electrodes and power supply rods are installed, an upper layer electrode and a lower layer electrode having the same configuration as the combination electrode 66 may be installed. In this case, one serves as a chuck electrode while the other serves as a high frequency electrode. A chuck power supply rod as a functional rod member is electrically connected to the chuck electrode, and a high frequency power supply rod is electrically connected to the high frequency electrode. Insertion of the chuck power supply rod and the high frequency power supply rod into respective protection pipes 60 and their subordinate structures are completely same as those of the other functional rod members 62.

Further, a ground electrode having the same configuration as the combination electrode 66 may be installed. In this case, by grounding a lower end of a functional rod member 62 connected thereto, the ground electrode may be grounded.

Moreover, although the present embodiment has been described for the plasma film forming apparatus, the present invention is not limited thereto but can be applied to various kinds of apparatuses using the mounting table structure in which the heating unit 64 is embedded in the mounting table 58. For example, the present invention can be applied a thermal film forming apparatus, an etching apparatus, a thermal diffusing apparatus, a diffusing apparatus, a property modification apparatus or the like. If unnecessary, the combination electrode 66 (including the chuck electrode and the high frequency electrode), the thermocouple 80 or subordinate members thereof can be omitted.

Further, the gas supply unit is not limited to the shower head unit 24. For example, the gas supply unit may be a gas nozzle inserted through the inside of the processing chamber 22.

Moreover, although the thermocouples 80 and 196 are used here as a temperature measuring device, the present invention is not limited thereto. For instance, a radiation thermometer may be used. In such a case, an optical fiber used in the radiation thermometer to transmit light may serve as a functional rod member and may be inserted into the protection pipes 60 or 60-1

In addition, although the above embodiment has been described for the case of accommodating one functional rod member 62 in one protection pipe 60, a plurality of functional rod members may be accommodated in a single protection pipe.

Furthermore, although the semiconductor wafer has been described as the processing target object herein, the present invention is not limited thereto. For example, the processing target object may be a glass substrate, a LCD substrate, a ceramic substrate, or the like.

The above description of the present invention is provided for the purpose of illustration, and it would be understood by those skilled in the art that various changes and modifications may be made without changing the technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A mounting table structure provided within a processing chamber of a processing apparatus so as to mount thereon a target object to be processed, the processing chamber having a bottom, the mounting table structure comprising:
a mounting table, including a heating unit and made of a dielectric material, configured to mount the target object thereon;
a cylindrical supporting column, which is extended upward from the bottom of the processing chamber and made of a dielectric material, configured to detachably support the mounting table;
a cylindrical protection pipe having an upper end joined to a bottom surface of the mounting table and made of a dielectric material having a diameter smaller than a diameter of the supporting column; and
a functional rod member inserted through an inside of the protection pipe and having an upper end in contact with the mounting table.

2. The mounting table structure of claim 1, wherein a venthole is provided in a sidewall of the supporting column.

3. The mounting table structure of claim 1, wherein the protection pipe is joined to a central portion of the mounting table.

4. The mounting table structure of claim 1, wherein the protection pipe is joined to a peripheral portion of the mounting table.

5. The mounting table structure of claim 1, wherein the protection pipe is accommodated in the supporting column.

6. The mounting table structure of claim 1, wherein one or a plurality of the functional rod members are accommodated in the one protection pipe.

7. The mounting table structure of claim 1, wherein a lower end of the protection pipe is connected to the bottom of the processing chamber via an expansible/contractible bellows.

8. The mounting table structure of claim 1, wherein a nonreactive gas vessel is installed at a lower end of the protection pipe, and an inside of the protection pipe is under an atmosphere of a nonreactive gas from the nonreactive gas vessel.

9. The mounting table structure of claim 1, wherein a spring member is provided to the functional rod member, and the functional rod member is pressed toward the mounting table by the spring member.

10. The mounting table structure of claim 1, wherein the mounting table and the supporting column are connected by a connecting pin.

11. The mounting table structure of claim 1, wherein the mounting table and the supporting column are connected by a hole bolt having a lifter pin hole in a central portion thereof and a fastening nut screwed onto the hole bolt.

12. The mounting table structure of claim 1, wherein the functional rod member is a heater power supply rod electrically connected with the heating unit.

13. The mounting table structure of claim 1, wherein a chuck electrode for an electrostatic chuck is installed in the mounting table, and the functional rod member is a chuck power supply rod electrically connected with the chuck electrode.

14. The mounting table structure of claim 1, wherein a high frequency electrode to which a high frequency power is applied is installed in the mounting table, and the functional rod member is a high frequency power supply rod electrically connected with the high frequency electrode.

15. The mounting table structure of claim 1, wherein a combination electrode, which serves as both a chuck electrode for an electrostatic chuck and a high frequency electrode to which a high frequency power is applied, is installed in the mounting table, and the functional rod member is a combination power supply rod electrically connected with the combination electrode.

16. The mounting table structure of claim 1, wherein the functional rod member is a conductive rod of a thermocouple that measures a temperature of the mounting table.

17. The mounting table structure of claim 1, wherein the functional rod member is an optical fiber of a radiation thermometer that measures a temperature of the mounting table.

18. A processing apparatus that performs a process on a target object, the apparatus comprising:
an evacuable processing chamber having a bottom;
a mounting table structure configured to mount the target object thereon; and
a gas supply unit configured to supply a gas into the processing chamber,
wherein the mounting table structure includes:
a mounting table, including a heating unit and made of a dielectric material, configured to mount the target object thereon;
a cylindrical supporting column, which is extended upward from the bottom of the processing chamber and made of a dielectric material, configured to detachably support the mounting table;
a cylindrical protection pipe having an upper end joined to a bottom surface of the mounting table and made of a dielectric material having a diameter smaller than a diameter of the supporting column; and
a functional rod member inserted through an inside of the protection pipe and having an upper end in contact with the mounting table.
